(19) United States
(12) Patent Application Publication
(10) Pub. No.: US 2006/0051905 A1
(43) Pub. Date: Mar. 9, 2006

(54) Method of fabricating planarized poly-silicon thin film transistors

(76) Inventors: Hung-Tse Chen, Taipei Hsien (TW); Yu-Cheng Chen, Hsinchu City (TW); Chi-Lin Chen, Hsinchu City (TW)

Correspondence Address: RABIN & BERDO, P.C.;Suite 500, 1101 14 Street, N.W., Washington, DC, 20005, US

(21) Appl. No.: 11/200,139

(22) Filed: Aug. 10, 2005

(30) Foreign Application Priority Data
Sep. 7, 2004 (TW) 93127021

(51) Int. Cl. H01L 21/84; H01L 21/00

(52) U.S. Cl. 438/149

(57) ABSTRACT

A buffer layer, a protective layer and a poly-silicon layer are formed on a substrate in turn, and the poly-silicon layer is then patterned to form island active regions. Next, n-type ions are implanted into portions of the poly-silicon layer to form source/drain regions. Then, a dilute buffer oxide etchant is utilized to micro-etch the poly-silicon layer to change the surface morphology of the poly-silicon. Finally, a laser annealing process is performed to partially melt the poly-silicon for forming a smooth surface and activating the source/drain region of the poly-silicon simultaneously.

### RELATED APPLICATIONS

The present application is based on, and claims priority from, Taiwan Application Serial Number 93127021, filed Sep. 7, 2004, the disclosure of which is hereby incorporated by reference herein in its entirety.

### BACKGROUND OF THE INVENTION

1. Field of Invention

The invention relates to a method of fabricating poly-silicon thin film transistors and, in particular, to a method of fabricating planarized poly-silicon thin film transistors.

2. Related Art

Thin film transistors (TFT) have been widely used for driving active liquid crystal displays (LCD). In particular, the poly-silicon (poly-Si) TFT apparently has a higher electron mobility and thus receives much attention in the applications of LCD in recent years. The advantage of the poly-Si TFT is the ability of making a display with a fast response speed and a high resolution. It is particularly suitable for integrating a driving circuit onto the display panel.

However, aside from the control in grain sizes, an existing technical problem in fabricating poly-Si TFT's is that the surface of poly-Si is normally too rough. As the grain size becomes larger, the poly-Si surface gets rougher. This will have bad influences on the electrical properties of devices. For example, the threshold voltage Vth, breakdown electric field, leak current, and electron mobility are affected by the roughness of the poly-Si surface.

Due to the rough surface of poly-Si, the thin film (e.g. gate oxide layer) subsequently formed on its surface will have an inhomogeneous thickness. The ridge part of the poly-Si layer is likely to have a large electric field, causing the breakdown of the gate oxide layer and enlarging the leak current. The device reliability is thus lowered. For devices that have special requirements for the thin gate oxide layers, the above-mentioned problems are more serious. Moreover, in the photolithography process, the roughness of the poly-Si surface will result in random scattering during the exposure and thus errors in size definitions. Therefore, the rough surface of poly-Si does not only have poor effects on the electrical properties of the device, it also lowers the product yield of the TFT devices.

Although there are literatures and patents pointing out methods to improve the rough poly-Si surface using the chemical mechanical polishing (CMP) process, this cannot be applied to fabricate large-area displays. Moreover, this method can only achieve limited improvement in the surface roughness of poly-Si, with an average roughness of 30˜40 angstrom (Å). Therefore, the method is not suitable for the trend in recent years to make large-area displays and smaller devices.

U.S. 2004/0055999 proposes a method that changes the surface morphology of poly-Si by etching and planarizes the surface by combining with a laser annealing process. However, directly applying this method in the fabrication of the TFT devices requires the additional laser process. In particular, for the N-type metal oxide semiconductor (MOS) TFT that needs to go through an activation process, there involve even more steps and a higher production cost.

### SUMMARY OF THE INVENTION

An object of the invention is to provide a method of fabricating planarized poly-Si TFT's used in the production of TFT's for driving displays. The planarization process is integrated into the production of poly-Si TFT's, so that the same laser annealing process can also achieve the goal of planarizing poly-Si and activating source/drain regions.

In accord with the above object, the invention provides a method of fabricating planarized poly-Si TFF's. A buffer layer, a protective layer and a poly-silicon layer are formed in sequence on a substrate. The buffer layer is made of, for example, silicon oxide. The protective layer uses an insulating material that is resistive to the silicon oxide etching environment. It has to have a high etching selection ratio relative to silicon oxide, e.g. silicon nitride and SiOₓN_{y}, to protect the buffer from the damages of silicon oxide in the subsequent planarization process. Besides, the poly-Si layer can be formed directly by chemical vapor deposition (CVD) of poly-Si or first depositing an amorphous (a-Si) layer and then turning the a-Si layer into a poly-Si layer by laser crystallization.

The poly-Si layer is then patterned to form island active regions, exposing the protective layer on both sides of each island active region. Next, N-type ions are implanted into the island active regions to form source/drain regions in the poly-Si layer. The source/drain regions thus formed are of the N-type.

After defining island active regions and implanting ions, the poly-Si layer undergoes a surface planarization process. The surface of the poly-Si surface is micro-etched to change its surface morphology. Afterwards, a laser annealing process is performed to partially melt the poly-Si layer for forming a smoother surface and activating the source/drain regions on the poly-Si layer simultaneously. The micro-etching step involves a wet etching that uses a buffer oxide etchant to remove the native oxide layer on the poly-Si surface and the part with weaker bonds in the poly-Si lattice. This achieves the effect of reducing the surface roughness. The laser beam energy used in the laser annealing process is lower than the laser crystallization energy for melting the poly-Si layer, e.g. 200˜350 mJ/cm². Therefore, it can achieve the simultaneous effects of planarizing the surface of the poly-Si layer and activating the source/drain regions on the poly-Si layer.

After the above steps, a dielectric layer can be formed on the poly-Si layer. The poly-Si layer is then patterned to form contact holes in the dielectric layer for exposing the source/drain regions in the poly-Si layer. Finally, a gate metal and source/drain metals are formed. In particular, the gate metal is on the dielectric layer. The source/drain metals are located in the contact holes. This finally completes the fabrication of a planarized poly-Si TFT.

According to the above-mentioned embodiment, the planarization is performed after defining the active regions and implanting ions in the poly-Si layer. The laser annealing conditions are controlled so that the surface planarization and the activation of the source/drain regions are done is the same step. Therefore, a planarized TFT device can be fabricated without modifying existing production processes.

Since the invention can combine the surface planarization and source/drain region activation together in the same laser process, the number of steps in the method is reduced. This is particularly convenient for making N-type TFT devices that require activation.

According to the disclosed method, the average roughness of the poly-Si surface is efficiently reduced down to below 30 Å. Therefore, the disclosed fabrication method can not only greatly increase the electrical properties and reliability of TFT devices, but also helps improving the quality in the subsequent fabrication of thin film layers and increasing the production yield.

Besides, a protective layer is provided between the poly-Si layer and the buffer layer to block all possible damages on the buffer layer due to the etching conditions of the micro-etching. The protective layer separates the buffer layer to ensure the device quality.

### BRIEF DESCRIPTION OF THE DRAWINGS

These and other features, aspects and advantages of the invention will become apparent by reference to the following description and accompanying drawings which are given by way of illustration only, and thus are not limitative of the invention, and wherein:

FIG. 1 is a flowchart outlining the steps in the method of fabricating a planarized poly-Si TFT according to a preferred embodiment of the invention; and

FIGS. 2A to 2F are schematic cross-sectional views of making a planarized poly-Si TFT according to a preferred embodiment of the invention.

### DETAILED DESCRIPTION OF THE PREFERRED EMBODIMENT

The invention combines the planarization of the poly-Si surface with the activation process in the usual TFT fabrication. By using the laser annealing technique, the roughness of the poly-Si surface can be reduced and the source/drain regions in the poly-Si can be activated simultaneously. The protective layer can prevent the buffer from being damaged by the etchant in wet etching. We use the following embodiment to explain the disclosed method.

### Embodiment

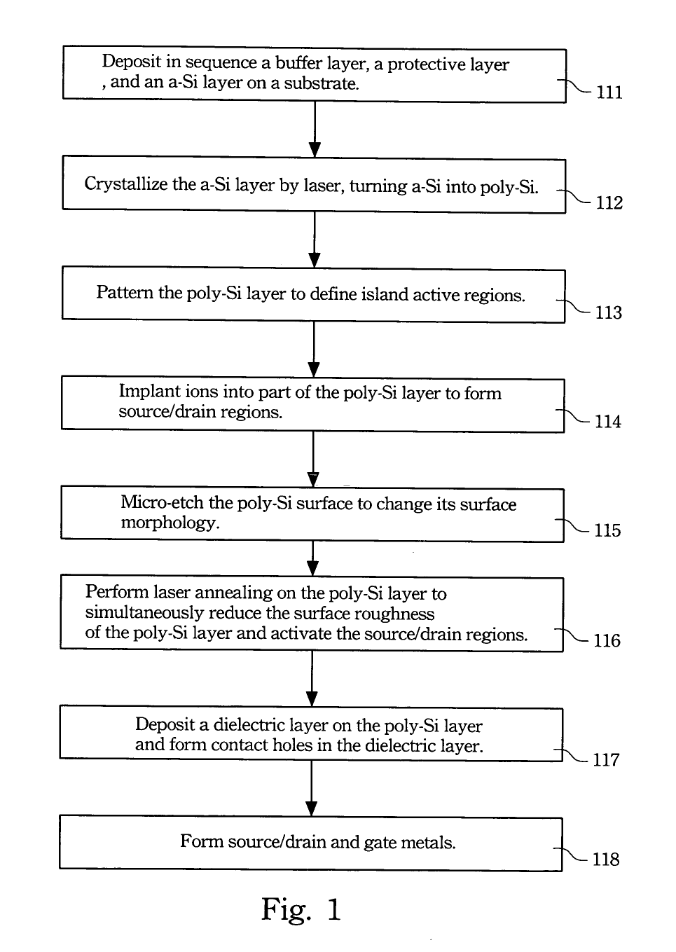

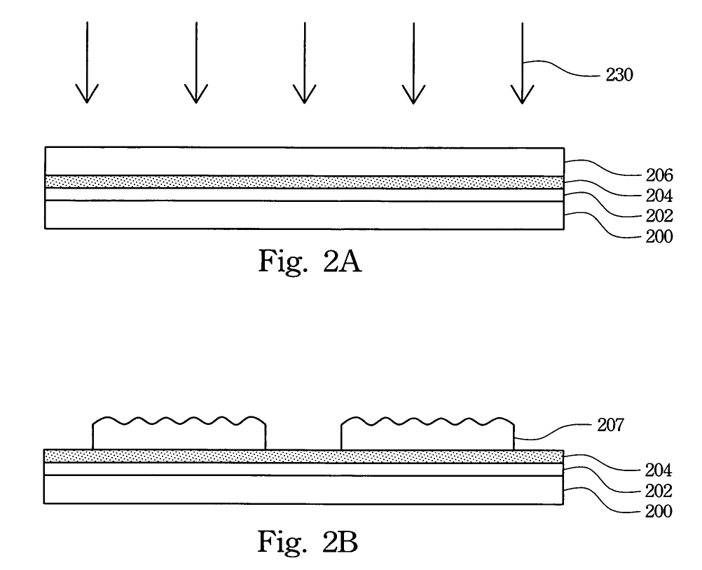

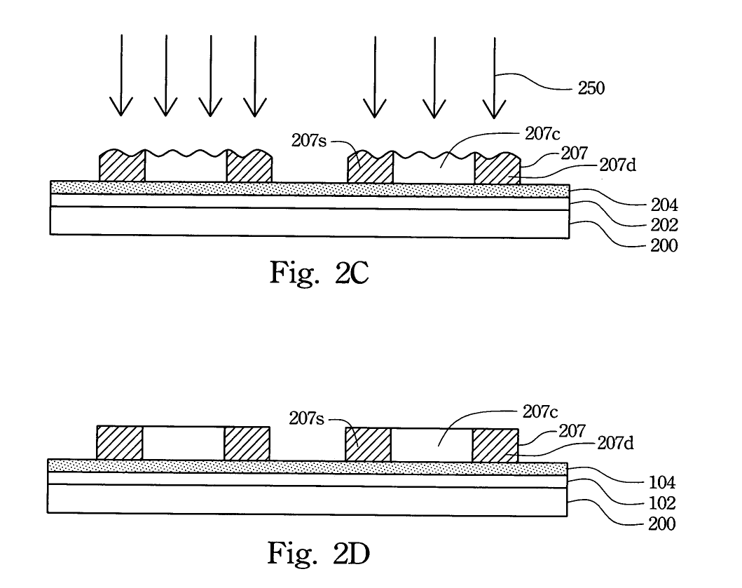

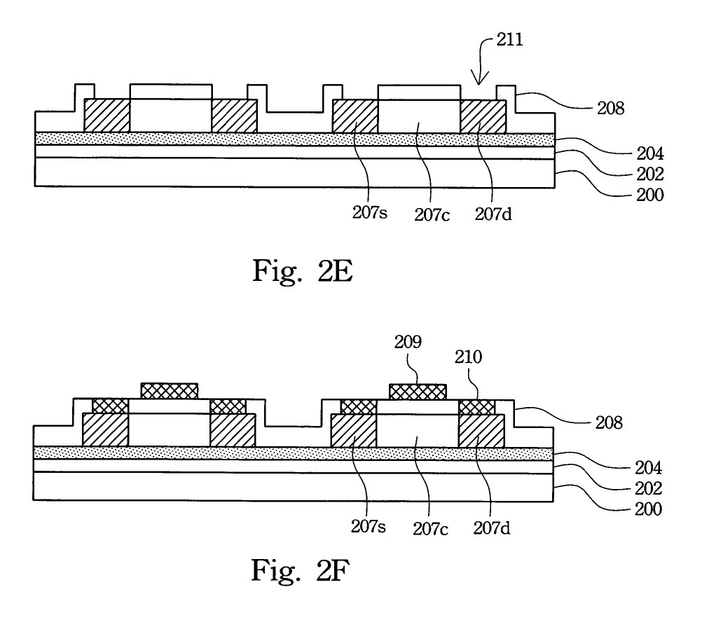

The disclosed method of fabricating planarized poly-Si TFT's is illustrated in FIGS. 1 and 2A to 2F. FIG. 1 shows the flowchart of the method according to the preferred embodiment. FIGS. 2A to 2F are schematic cross-sectional views of fabricating the planarized poly-Si TFT.

This embodiment uses the fabrication of an N-type TFT as an example. First, step 111 in FIG. 1 is performed to deposit on a substrate 200 in sequence a buffer layer 202, a protective layer 204, and an a-Si layer 206, as shown in FIG. 2A. For the production of displays, the substrate 200 can be glass, the buffer layer 202 can be a silicon oxide layer, and the protective layer 204 can be an insulating material that is resistive to a silicon oxide etching environment. Such an insulating material, such as silicon nitride (SiNx) and SiOₓN_{y}, has a high etching selection ratio than silicon oxide to protect the buffer layer 202. Therefore, in subsequent planarization of the poly-Si surface, the buffer layer 202 will not be damaged by the wet silicon oxide etchant or plasma silicon oxide etching environment. The thickness of the protective layer 204 is preferably less than 1000 Å.

Afterwards, step 112 in FIG. 1 is performed to irradiate the a-Si layer 206 in FIG. 2A with a laser beam 230. The a-Si layer 206 is heated to crystallize, turning into a poly-Si layer. Because of the crystallization, the surface of the poly-Si layer becomes rough (as shown by the poly-Si layer 207 in FIG. 2B). The laser beam 230 can be obtained from an excimer laser with an ultraviolet (UV) emission of xenon chloride (XeCl). However, though the poly-Si layer 207 is formed using laser crystallization, it can be formed using the CVD method too.

When the a-Si layer 206 turns into poly-Si, as shown in FIG. 2B, step 113 in FIG. 1 is performed to pattern the poly-SI layer 207 for defining active regions on silicon islands. The patterning step is the usual photolithography etching process.

Afterwards, step 114 in FIG. 1 is performed implant ions on both sides of the island in the poly-Si layer 207 in FIG. 2B, forming the source region 207s and the drain region 207d in FIG. 2C. The poly-Si region between the source region 207s and the drain region 207d is the channel region 207c. In this case, the implanted ions are N-type dopants, such as the element P.

With reference to FIG. 2C, step 115 in FIG. 1 is performed to micro-etch the surface of the poly-Si layer 207 by wet etching. It changes the surface morphology of the poly-Si layer 207. The etchant can be a dilute buffer oxide etchant (BOE) or a dilute HF (DHF) aqueous solution for wet etching. The native oxides and the part with weaker bonds are then removed from the poly-Si layer 207. This can reduce the surface roughness of the poly-Si layer 207.

The above-mentioned BOE is composed of HF, NH₄F, and water. The ratio between the HF(49%) and H₂O+NH₄F is between 1:1 and 1:20, the best condition is 1:4. Although this embodiment uses wet etching to process the surface of the poly-Si layer 207, a plasma dry etching using with the same conditions, such as a gas containing CF4, can achieve the same effect too.

In step 115, the etching conditions in either wet etching or plasma dry etching can easily etch the silicon oxide film. The protective layer 204 formed in the embodiment has the ability to block etching, preventing the buffer layer 202 from damages of the etching solution or gas. Therefore, the buffer layer 202 can still separate devices from the substrate 200.

Afterwards, step 116 in FIG. 1 is performed, with simultaneous reference to FIG. 2C. Another laser beam 250 is used to irradiate the poly-Si layer 207 for laser annealing. In such a process, one may use an excimer laser containing an UV emission of XeCl. The laser energy used in this step is lower than that for completely melting poly-Si. For example, the energy is lower than the energy of the laser beam 230 for crystallizing a-Si in this embodiment, but is sufficiently strong to activate the source region 207s and the drain region 207d in the poly-Si layer. A preferred laser energy range is 200˜350 mJ/cm².

In step 116 of laser annealing, the surface of the poly-Si layer 207 is irradiated to partially melt the poly-silicon for forming a smooth surface, achieving the effect of surface planarization. Due to the choice of laser energy, the source region 207s and the drain region 207d in the N-type ion doped poly-Si layer 207 can be activated simultaneously.

The surface planarization of the poly-Si layer is achieved by the micro-etching in step 115 and the laser annealing process in step 116. The surface roughness of the poly-Si layer 207 is greatly reduced, as shown in FIG. 2D. Moreover, the invention is featured in that the laser annealing process in step 116 simultaneously activates the source/drain regions.

Finally, steps 117 and 118 in FIG. 1 are performed in sequence to complete the fabrication of the TFT. Step 117, as shown in FIG. 2E, deposits a dielectric layer on the poly-Si layer 207. The dielectric layer 208 is patterned to form contact holes 211. Step 118, as shown in FIG. 2F, forms a gate metal 209 on the dielectric layer 208 and source/drain metals 210 in the contact holes 211. The gate metal 209 is disposed above the channel region 207c of poly-Si. The source/drain metals 210 are disposed above the source region 207s and the drain region 207d of poly-Si.

The material of the dielectric layer 208 is silicon oxide. The gate metal 209 and the source/drain metals 210 are made of metals with good electrical conductivity, such as Mo, MoW, and Al.

Using the disclosed method, one can obtain a planarized poly-Si TFT without modifying the existing TFT fabrication process. After defining the active regions and ion implantation, the poly-Si layer is planarized. Through the control of laser annealing conditions, the planarization of the poly-Si surface and the activation of the source/drain regions in poly-Si are completely simultaneously.

The invention combines the processes of poly-Si planarization and source/drain region activation in one laser process. Therefore, the number of steps involved in the procedure can be effectively reduced. In particular, for N-type TFT devices that require an activation process, a planarized TFT device can be obtained without increasing the complexity of the fabrication method.

In accord with the embodiment, the method can reduce the average roughness of the poly-Si surface down to less than 30 angstrom. Therefore, not only can the disclosed method enhance the electrical properties of the TFT device, a higher reliability can be obtained also. This is suitable for the quality control in subsequent TFF fabrication and for increasing the yield.

Moreover, by installing a protective layer between the poly-Si layer and the buffer, the invention can avoid possible damages on the buffer layer due to the stringent etching condition in the micro-etching for changing the surface morphology of poly-Si. The buffer layer thus can separate devices from the substrate.

It should be emphasized that the disclosed method is not limited to the fabrication of N-type MOS TFT's. The product efficiency of any poly-Si TFT driving device can be enhanced using the invention.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of fabricating a planarized poly-silicon (poly-Si) thin film transistor (TFT), comprising the steps of:
forming a buffer layer on a substrate;
forming a protective layer on the buffer layer;
forming a poly-Si layer on the protective layer;
patterning the poly-Si layer to form at least one island active region and exposing the protective layer from both sides of the island active region;
implanting ions into part of the island active region to form a source region and a drain region in the poly-Si layer;
micro-etching the surface of the poly-Si layer to change the surface morphology of the poly-Si layer; and
performing a laser annealing process to partially melt the poly-Si layer for forming a smooth surface and activating the source/drain regions of the poly-Si simultaneously.

2. The method of claim 1 further comprising the steps of:
forming a dielectric layer on the poly-Si layer;
patterning the dielectric layer to form a plurality of contact hole in the dielectric layer and expose the source region and the drain region of the poly-Si layer; and
forming at least a gate metal and a plurality of source/drain metals, wherein the gate metal is disposed on the dielectric layer and the source/drain metals are disposed in the contact holes.

3. The method of claim 1, wherein the substrate is made of glass.

4. The method of claim 1, wherein the buffer layer is a silicon oxide layer.

5. The method of claim 1, wherein the protective layer uses an insulating material that is resistive to a silicon oxide etching environment and has a higher etching selection ratio than silicon oxide.

6. The method of claim 5, wherein the protective layer is selected from the group comprising a silicon nitride layer and a SiOₓN_{y} layer.

7. The method of claim 5, wherein the thickness of the protective layer is less than 1000 angstrom (Å).

8. The method of claim 1, wherein the formation of the poly-Si layer is achieved by a method selected from the group comprising the method of directly depositing poly-Si by chemical vapor deposition (CVD) and the method of first forming an amorphous silicon (a-Si) layer followed by turning the a-Si into poly-Si using a laser crystallization technique.

9. The method of claim 1, wherein the source region and the drain region are N-type regions.

10. The method of claim 1, wherein the micro-etching step adopts a process selected from the group comprising wet etching and plasma dry etching.

11. The method of claim 10, wherein the wet etching is performed with a solution selected from the group comprising a dilute buffer oxide etchant (BOE) and a dilute HF (DHF) etchant.

12. The method of claim 1, wherein the laser energy used in the laser annealing process is lower than the laser energy for totally melting the poly-Si layer and sufficiently strong to activate the source region and the drain region in the poly-Si layer.

13. The method of claim 1, wherein the laser energy used in the laser annealing process is about 250˜350 mJ/cm².

14. A method of fabricating a planarized poly-Si TFT, comprising the steps of:
forming a buffer layer on a substrate;
forming a protective layer on the buffer layer;
forming an a-Si layer on the protective layer;
using a first laser beam to irradiate the a-Si layer, turning the a-Si layer into a poly-Si layer;
patterning the poly-Si layer to form at least one island active region and exposing the protective layer from both sides of the island active region;
implanting ions into part of the island active region to form a source region and a drain region in the poly-Si layer;
micro-etching the surface of the poly-Si layer to change the surface morphology of the poly-Si layer;
using a second laser beam to perform a laser annealing process on the poly-Si layer to partially melt the poly-Si layer for forming a smooth surface and activating the source/drain regions of the poly-Si simultaneously;
forming a dielectric layer on the poly-Si layer;
patterning the dielectric layer to form a plurality of contact hole in the dielectric layer and expose the source region and the drain region of the poly-Si layer; and
forming at least a gate metal and a plurality of source/drain metals, wherein the gate metal is disposed on the dielectric layer and the source/drain metals are disposed in the contact holes.

15. The method of claim 14, wherein the protective layer uses an insulating material that is resistive to a silicon oxide etching environment and has a higher etching selection ratio than silicon oxide.

16. The method of claim 15, wherein the protective layer is selected from the group comprising a silicon nitride layer and a SiOₓN_{y} layer.

17. The method of claim 15, wherein the thickness of the protective layer is less than 1000 angstrom (Å).

18. The method of claim 14, wherein the source region and the drain region are N-type regions.

19. The method of claim 14, wherein the micro-etching step adopts a process selected from the group comprising wet etching and plasma dry etching.

20. The method of claim 19, wherein the wet etching is performed with a solution selected from the group comprising a dilute BOE and a DHF etchant.

21. The method of claim 14, wherein the energy of the second laser beam is lower than the energy of the first laser beam.

22. The method of claim 14, wherein the laser energy of the second laser beam is about 200˜350 mJ/cm².
